(19) United States
(12) Patent Application Publication
(10) Pub. No.: US 2026/0362825 A1
(43) Pub. Date: Nov. 12, 2026

(54) SEMICONDCUTOR DEVICE AND METHOD OF MANUFACTURING THE SAME

(71) Applicant: Taiwan Semiconductor Manufacturing Company, Ltd., Hsinchu (TW)

(72) Inventors: Po-Chun Liu, Hsinchu City (TW); Kuei-Ming Chen, New Taipei City (TW)

(21) Appl. No.: 19/314,230

(22) Filed: Aug. 29, 2025

Related U.S. Application Data
(60) Provisional application No. 63/804,073, filed on May 12, 2025.

(51) Int. Cl. H10F 30/225; H10F 71/00; H10F 77/00

(52) U.S. Cl. CPC H10F 30/225; H10F 71/133; H10F 77/933

(57) ABSTRACT

Various embodiments of the present disclosure are directed towards a semiconductor device. The semiconductor device includes a substrate comprising a first material and opposing sidewalls defining a recess. A semiconductor structure is in the recess and comprises a second material different from the first material. A doped capping layer overlies the semiconductor structure. The doped capping layer has a first doping type. The doped capping layer covers a top surface of the semiconductor structure and extends laterally between opposing sidewalls of the semiconductor structure.

### BACKGROUND

A significant amount of development effort has been directed toward imaging and ranging integrated circuit (IC) devices. For example, such devices that operate in the infrared (IR) bandwidth range may employ single-photon avalanche diodes (SPADs), which may produce a measureable current pulse in response to the reception of a single photon in the presence of a significant reverse bias voltage. In some cases, development of such devices may be focused on providing increased photon detection efficiency (PDE) (e.g., the probability that the SPAD produces a valid output signal in response to a received photon) and reduced dark count rate (DCR) (e.g., the rate at which output signals are generated in the absence of received photons).

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1A illustrates a cross-sectional view of some embodiments of an integrated circuit (IC) device employing a single-photon avalanche diode (SPAD) with a graded doping structure in a photon absorption region of the SPAD, according to the present disclosure.

FIG. 1B illustrates a graph illustrating some embodiments of material concentrations of layers of the graded doping structure in the SPAD of FIG. 1A.

FIGS. 1C and 1D are plan views of some embodiments of the IC device of FIG. 1A, according to the present disclosure.

FIG. 1E illustrates a cross-sectional view of some embodiments of an IC device employing a SPAD with another graded doping structure in a photon absorption region of the SPAD, according to the present disclosure.

FIGS. 2A through 2U illustrate cross-sectional views of some embodiments of an IC device employing a SPAD with a graded doping structure at various stages of manufacture, according to the present disclosure.

FIG. 3 illustrates a cross-sectional view of some embodiments of another IC device employing a SPAD with a graded doping structure, according to the present disclosure.

FIGS. 4 and 5 illustrate block diagrams of some embodiments of methodologies of forming an IC device including a SPAD having a graded doping structure, according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

A significant goal regarding the design of single-photon avalanche diodes (SPADs) (e.g., infrared (IR) SPADs, such as those configured to detect photons with wavelengths greater than 1310 nanometers (nm)) is to maintain an acceptable increased photon detection efficiency (PDE) of a SPAD while minimizing its dark count rate (DCR). In some cases, a SPAD using an intrinsic semiconductor material for an absorption region (e.g., for receiving a photon) of the SPAD may include a “guard ring” to reduce the instance of premature voltage breakdown at the edge of the absorption region (e.g., near the interface between the intrinsic semiconductor material and a surrounding doped semiconductor region, which may be referred to as an “electron channel”) to suppress unwanted dark current. However, in such cases, dark current may remain undesirably high between the intrinsic semiconductor material and an opening of the electron channel at a multiplication or “avalanche” region in which the output current is generated. Further, in at least some circumstances, the PDE of a SPAD may be linearly related to the DCR of the SPAD, such that increasing the PDE (e.g., by increasing the excess reverse bias voltage over the breakdown voltage of the SPAD) may increase the DCR by a corresponding percentage.

To address these issues, the present disclosure provides some embodiments of an IC imaging device (e.g., an IR imaging device include one or more SPADs) that includes a doped semiconductor structure in which the doping concentration of the structure varies from a relatively low concentration near an interface between the structure and a surrounding semiconductor layer to a higher concentration near a central region of the structure. In some embodiments, the structure may include a plurality of doped layers, in which the doping concentration of each layer progressively increases from layer to layer. In other embodiments, the structure may include a concentration gradient that generally increases from the interface between the structure and the surrounding semiconductor layer to the central region of the structure. Also, in some embodiments, the use of a doped semiconductor structure may reduce or eliminate the need for a guard ring.

Consequently, in some embodiments, by reducing the doping concentration near the interface between the doped semiconductor structure and the surrounding semiconductor layer, the DCR of the associated SPAD may be decreased relative to a SPAD employing an intrinsic semiconductor that includes a guard ring operated at the same excess reverse bias voltage over the breakdown voltage. For example, in some embodiments, the increased doping concentration at or near the central region of the doped semiconductor structure may promote electron recombination, and thus reduce the DCR, while the low doping concentration at the interface between the structure and the surrounding semiconductor layer may simultaneous provide a high PDE for the SPAD. In some embodiments, a disclosed IC imaging device may be able to achieve a PDE of greater than 15% with a DCR of less than 20 MHZ. In some embodiments, the graded doping concentration of the doped semiconductor structure may facilitate a higher slope for the PDE-to-DCR linear relationship, thus possibly resulting in a higher PDE for a comparable DCR relative to a SPAD using an intrinsic semiconductor and associated guard ring, thereby potentially resulting in a higher-performance SPAD. Further, in some embodiments, the elimination of a guard ring may simplify the fabrication of the IC device by reducing the number of photomasks employed.

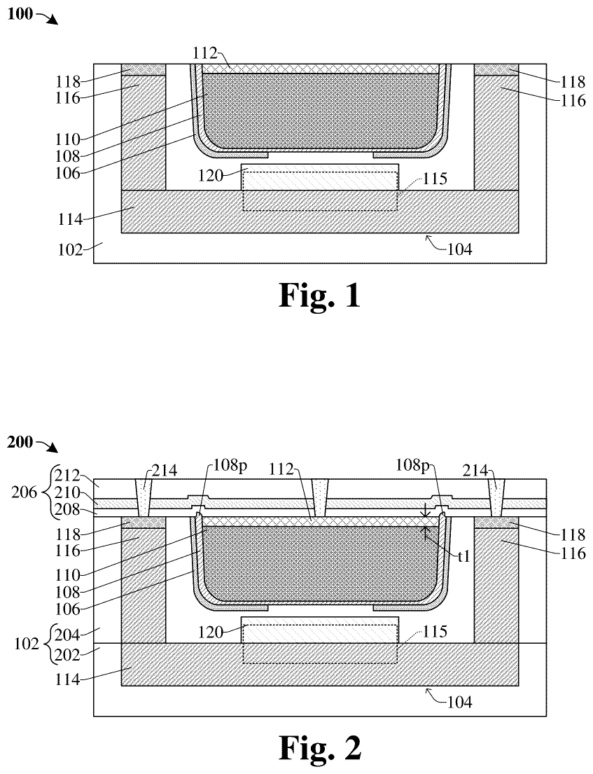

FIG. 1A illustrates a cross-sectional view of some embodiments of an integrated circuit (IC) device 100 employing a single-photon avalanche diode (SPAD) 101 with a graded doping structure in a photon absorption region of SPAD 101, according to the present disclosure. The particular embodiments of FIG. 1A, as described in greater detail below, employ multiple doped layers in the absorption region, each having a different corresponding concentration. In other embodiments, a continuous concentration gradient may be employed in lieu of multiple doped layers.

In FIG. 1A, IC device 100 includes a semiconductor substrate 102 (e.g., a silicon (Si) substrate) having a doped floor region 104 (e.g., a lower n-doped structure, or an array deep n-well photodiode (ADNP) region) at an upper side of semiconductor substrate 102. Further, IC device 100 may include a semiconductor layer 106 (e.g., a silicon (Si) layer) on semiconductor substrate 102. In some embodiments, semiconductor layer 106 is an epitaxial layer grown on semiconductor substrate 102.

In some embodiments, semiconductor layer 106 may include a doped wall region 110 (e.g., an n-doped wall region, or a deep n-doped well (DNW)) on doped floor region 104. In some embodiments, doped wall region 110 may extend upward and may be located on or at a lateral peripheral edge of doped floor region 104 (e.g., where an outer side of doped wall region 110 aligns with a lateral side of doped floor region 104). Further, while the cross-sectional view of FIG. 1A may imply the possible presence of separate doped wall regions 110, in some embodiments, as described in greater detail below with respect to FIGS. 1C and 1D, doped wall region 110 may be a single structure that partially or fully encloses a central region of semiconductor layer 106 over doped floor region 104. Further, in some embodiments, other portions of IC device 100 associated with doped wall region 110 may also be incorporated in a single structure.

For example, in some embodiments, semiconductor layer 106 may include an upper doped region 112 (e.g., an upper n-doped region) that may be disposed at an upper end, or on top, of doped wall region 110. Further, in some embodiments, upper doped region 112 may be more heavily doped (e.g., have a higher doping concentration) than doped wall region 110. Also in semiconductor layer 106, in some embodiments, a lower doped region 108 (e.g., a lower p-doped region, or an array p-doped well (APW)) located on doped floor region 104 within semiconductor layer 106 (e.g., within a multiplication or avalanche layer of SPAD 101 of IC device 100). Moreover, in some embodiments, an upper doped region 126 (e.g., an upper p-doped region, or a cell p-doped region) of an upper semiconductor layer 128 may be located over lower doped region 108 at an upper side of semiconductor layer 106.

In some embodiments, a doped semiconductor structure 125 is provided for an absorption region of a SPAD 101 (e.g., located over lower doped region 108). In embodiments depicted in FIG. 1A, doped semiconductor structure 125 may include a plurality of doped layers 120, 122, and 124. While three doped layers 120, 122, and 124 are illustrated in FIG. 1A, other numbers of layers (e.g., two layers, four layers, five layers, and so forth) may be used in other embodiments.

More specifically, in some embodiments, a first doped layer 120 may form a first side of doped semiconductor structure 125 that faces toward doped wall region 110 (e.g., facing laterally outward) and doped floor region 104 (e.g., facing downward). Aligned atop and along first doped layer 120 may be a second doped layer 122. Further, a third doped layer 124 may be aligned atop and along second doped layer 122, and may also fill a void formed by second doped layer 124. Consequently, the plurality of doped layers 120, 122, and 124 may form a second side (e.g., an upward facing side) of doped semiconductor structure 125.

In some embodiments, each doped layer 120, 122, and 124 includes a semiconductor material (e.g., germanium (Ge), silicon-germanium (SiGe), and/or germanium-tin (GeSn)) doped with doping material (e.g., boron (B), thus forming a p-type semiconductor material). Further, in some embodiments, each doped layer 120, 122, and 124 may possess a different concentration of the doping material such that the concentrations increase from the first side of doped semiconductor structure 125 (e.g., first doped layer 120) to a central area of the second side of doped semiconductor structure 125 (e.g., third doped layer 124). In such cases, the doping material concentration of third doped layer 124 is greater that the doping material concentration of second doped layer 122, and the doping material concentration of second doped layer 122 is greater than the doping material concentration of first doped layer 120. For example, first doped layer 120 may have a doping material concentration in a range of 7×10¹⁶ atoms per cubic centimeter (atoms/cm³) to 2×10¹⁷ atoms/cm³ (e.g., approximately 1×10¹⁷atoms/cm³ ), second doped layer 122 may have a doping material concentration in a range of 3×10¹⁷ atoms/cm³ to 7 ×10¹⁷ atoms/cm³ (e.g., approximately 5×10¹⁷atoms/cm³ ), and third doped layer 124 may have a doping material concentration in a range of 8×10¹⁷ atoms/cm³ to 5×10¹⁸ atoms/cm³ (e.g., approximately 1×10¹⁸ atoms/cm³).

In some embodiments, each doped layer 120, 122, and 124 may be conformally deposited semiconductor material (e.g., germanium (Ge)) that is doped in-situ (e.g., added to the sputtering, deposition, or other process gas used for deposition) with a doping material (e.g., boron (B)). In some embodiments, the thickness of first doped layer 120 may be in a range of 50 nm to 100 nm, or approximately 75 nm), and the thickness of second doped layer 122 may be in a range of 50 nm to 500 nm, or approximately 300 nm). Consequently, as third doped layer 124 may fill the remaining volume of doped semiconductor structure 125, the thickness and overall volume of third doped layer 124 may be significantly greater than both first doped layer 120 and second doped layer 122.

In some embodiments, IC device 100 may include a doped channel structure 114 (e.g., a p-doped channel structure) that substantially covers the first side of doped semiconductor structure 125 (e.g., along and near first doped layer 120), and may include an opening 116 between first doped layer 120 and lower doped region 108. Further, in some embodiments, an additional semiconductor layer 118 may reside between doped channel structure 114 and first doped layer 120.

In some embodiments, one or more dielectric layers 130, which may include one or more insulating barrier layers 132, may be located on doped semiconductor structure 125, upper doped regions 112 and 126, semiconductor layer 106, and upper semiconductor layer 128. In addition, in some embodiments, one or more conductive contacts 136 may be located within dielectric layers 130. Further, each conductive contact 136, possibly lined with a conductive barrier layer 134, may be electrically coupled to one of upper doped regions 112 and 126. Dielectric layers 130 may include silicon oxide (e.g., SiOₓ, such as silicon dioxide (SiO₂)), titanium oxide (TiO or TiO₂), barium oxide (BaO), tantalum oxide (Ta₂O₅), tungsten oxide (WO₃), molybdenum oxide (MoO₃), hafnium oxide (HfO₂), yttrium oxide (Y₂O₃), aluminum oxide (Al₂O₃), lanthanum oxide (La₂O₃), zirconium oxide (ZrO₂), silicon nitride (Si₃N₄), another oxide, or another dielectric (e.g., a high-k dielectric) material. In some embodiments, insulating barrier layer 132 may include, for example, silicon nitride (Si₃N₄) or another dielectric material. In some embodiments, conductive contacts 136 may include copper (Cu), tungsten (W), aluminum (Al), or another conductive material. Further, in some embodiments, conductive barrier layer 134 may include tantalum nitride (TaN), titanium nitride (TiN), or another conductive material.

FIG. 1B illustrates a graph 150 illustrating some embodiments of material concentrations of layers of the graded doping structure in the SPAD of FIG. 1A. More specifically, graph 150 depicts a semiconductor concentration 152 and an associated doping material concentration 154 for first doped layer 120, second doped layer 122, and third doped layer 124 of doped semiconductor structure 125 along a vertical depth therein. In some embodiments, the concentration axis (e.g., in atoms/cm³) may be viewed as a logarithmic axis, and the depth axis (e.g., in nm) may be interpreted as a linear axis. Consequently, semiconductor concentration 152 may be several or many times greater than doping material concentration 154 in each of first doped layer 120, second doped layer 122, and third doped layer 124. Further, semiconductor concentration 152 may be relatively constant throughout first doped layer 120, second doped layer 122, and third doped layer 124.

FIGS. 1C and 1D are plan views of some embodiments of the IC device 100 of FIG. 1A, according to the present disclosure. For example, FIG. 1C is a plan view of IC device 100 in which the plurality of doped layers 120, 122, and 124, doped channel structure 114, and doped wall region 110 are depicted as circular structures. FIG. 1D is a plan view of IC device 100 in which the same semiconductor structures appear as square structures. These structures may possess other shapes (e.g., rectangles, squares or rectangles with rounded edges, etc.) in other embodiments.

FIG. 1E illustrates a cross-sectional view of some embodiments of an IC device 100A employing a SPAD 101A with another graded doping structure in a photon absorption region of SPAD 101A, according to the present disclosure. Instead of doped semiconductor structure 125 including distinct doped layers 120, 122, and 124, each of which has a corresponding doping material concentration, as illustrated in FIG. 1A, FIG. 1E depicts doped semiconductor structure 125 as a single doped region that may have a continuous gradient doping material concentration profile. Moreover, in some embodiments, the doping material concentration may generally increase from the first side of doped semiconductor structure 125 (e.g., at or near doped channel structure 114) to the second side of doped semiconductor structure 125 (e.g., at an upper side of doped semiconductor structure 125 near upper doped region 126), as shown by the bold arrows in FIG. 1E. Further, in some embodiments, the doping concentration of doped semiconductor structure 125 at the first side may range from 7×10¹⁶ atoms/cm³ to 2×10¹⁷ atoms/cm³ (e.g., approximately 1×10¹⁷atoms/cm³ ), and the doping concentration at the second side, or at a central region 117 of doped semiconductor structure 125, may range from 8×10¹⁷ atoms/cm³ to 5×10¹⁸ atoms/cm³ (e.g., approximately 1×10¹⁸ atoms/cm³). Further, in some embodiments, the majority of the increase in doping concentration may occur within 100 nm to 600 nm (e.g., approximately 300 nm) of the first side of doped semiconductor structure 125.

In operation, in some embodiments associated with IC devices 100 and 100A, conductive contact 136 coupled to upper doped region 126 may serve as an anode for SPAD 101 and 101A, and conductive contact 136 coupled to upper doped region 112 may operate as a cathode for SPAD 101 and 101A. Thus, in some embodiments, when applying a reverse bias voltage in excess of the SPAD breakdown voltage (e.g., approximately 2-3 volts (V) greater than the breakdown voltage), a photon received in the absorption region (e.g., doped semiconductor structure 125, which may receive the photon from below) may cause SPAD 101 and 101A to create a measurable current pulse in the multiplication or avalanche region (e.g., including doped floor region 104 and lower doped region 108). As indicated above, SPAD 101 and 101A may facilitate a high PDE and low DCR compared to the use of an intrinsic semiconductor in the absorption region in conjunction with a guard ring.

FIGS. 2A through 2U illustrate cross-sectional views of some embodiments of an IC device (e.g., IC device 100) employing a SPAD (e.g., SPAD 101) with a graded doping structure at various stages of manufacture, according to the present disclosure. Although FIGS. 2A through 2U are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part.

For example, FIG. 2A illustrates semiconductor substrate 102 (e.g., a silicon (Si) substrate or the like). In some embodiments, semiconductor substrate 102 may serve as a substrate upon which other elements or structures shown in FIG. 1A are formed.

FIG. 2B illustrates the forming (e.g., by way of implantation or doping) of doped floor region 104 on semiconductor substrate 102 (e.g., at an upper side of semiconductor substrate 102). In some embodiments, a photoresist layer 202 is employed to expose the area of semiconductor substrate 102 on which ion plantation is to occur. Also, in some embodiments, implantation may be performed using a gas source 204 (e.g., arsenic (As) or phosphorus (P)) to create an n-doped floor region.

FIG. 2C illustrates the forming (e.g., by way of epitaxial growth) of semiconductor layer 106 on semiconductor substrate 102. In some embodiments, semiconductor layer 106 may include silicon (Si) or another semiconductor that may be grown epitaxially.

FIG. 2D illustrates the forming (e.g., by way of implantation or doping) of doped wall region 110 and upper doped region 112 (e.g., located over doped wall region 110) over a lateral end or edge of doped floor region 104. In some embodiments, an outer lateral side of doped wall region 110 and upper doped region 112 may align with an outer lateral side of doped floor region 104. Also, in some embodiments, the implantation may be performed using a gas source 204 (e.g., arsenic (As) or phosphorus (P)) to create n-doped regions.

FIG. 2E illustrates the forming (e.g., by way of deposition) of dielectric layer 130 on semiconductor layer 106 and upper doped region 112. In some embodiment, dielectric layer 130 may include, but is not limited to, silicon oxide (e.g., SiOₓ, such as silicon dioxide (SiO₂)), titanium oxide (TiO or TiO₂), barium oxide (BaO), tantalum oxide (Ta₂O₅), tungsten oxide (WO₃), molybdenum oxide (MoO₃), hafnium oxide (HfO₂), yttrium oxide (Y₂O₃), aluminum oxide (Al₂O₃), lanthanum oxide (La₂O₃), zirconium oxide (ZrO₂), silicon nitride (Si₃N₄), another oxide, or another dielectric (e.g., a high-k dielectric) material.

FIG. 2F illustrates the removal (e.g., using photolithography and etching via photoresist layer 202) of a portion of dielectric layer 130 (e.g., over a region circumscribed by doped wall region 110 in a plan view of semiconductor layer 106) to form an opening 206. Further, FIG. 2G illustrates the removal (e.g., using photolithography and etching via the same photoresist layer 202) of a portion of semiconductor layer 106 over doped floor region 104 to form a cavity 208. In some embodiments, the cavity 208 may include a floor (e.g., over doped floor region 104) and a surrounding wall. In some embodiments, the wall may be angled such that an opening of cavity 208 is larger than the floor of the cavity 208 and coincides with opening 206 of dielectric layer 130. Further, in some embodiments, opening 206 and cavity 208 may be formed in a single operation.

FIG. 2H illustrates the forming (e.g., by way of implantation or doping) of lower doped region 108 (e.g., an array p-well region (APW)) on doped floor region 104 by way of photoresist layer 202. In some embodiments, an upper side of lower doped region 108 is located below the floor of cavity 208. Also, in some embodiments, the implantation may be performed using a gas source 210 (e.g., boron (B)).

FIG. 2I illustrates the forming (e.g., by way of implantation or doping) of doped channel structure 114 (e.g., a p-doped channel structure) along the wall and a lateral portion of the floor of cavity 208 by way of photoresist layer 202, thus leaving opening 116 in doped channel structure 114 over lower doped region 108. Also, in some embodiments, the implantation may be performed using a gas source 210 (e.g., boron (B)).

FIG. 2J illustrates the forming (e.g., by way conformal deposition or epitaxial growth) of an additional semiconductor layer 118 (e.g., silicon (Si)) on doped channel structure 114. In some other embodiments, the forming of doped channel structure 114 may be performed (e.g., via sub-implantation) such that a narrow portion of undoped semiconductor remains over doped channel structure 114. In yet other embodiments, additional semiconductor layer 118 may not be present in IC device 100.

FIGS. 2K, 2L and 2M illustrate the forming (e.g., by way of conformal deposition) of first doped layer 120, second doped layer 122, and third doped layer 124, respectively, of doped semiconductor structure 125. As indicated above, in some embodiments, each doped layer 120, 122, and 124 includes a semiconductor material (e.g., germanium (Ge), silicon-germanium (SiGe), and/or germanium-tin (GeSn)) doped with a doping material (e.g., boron (B), thus forming a p-type semiconductor material). More specifically, in some embodiments, each doped layer 120, 122, and 124 may be conformally deposited semiconductor material (e.g., germanium (Ge)) that is doped in-situ (e.g., added to the sputtering, deposition, or other process gas used for deposition) with a doping material (e.g., boron (B)). However, in some embodiments, the deposition of third doped layer 124 may not be conformal. Further, in some embodiments, each doped layer 120, 122, and 124 may possess a different thickness. Also, each doped layer 120, 122, and 124 may possess a different concentration of the doping material such that the concentrations increase from the first side of doped semiconductor structure 125 (e.g., first doped layer 120) to a central area of the second side of doped semiconductor structure 125 (e.g., third doped layer 124). In such cases, the doping material concentration of third doped layer 124 is greater that the doping material concentration of second doped layer 122, and the doping material concentration of second doped layer 122 is greater than the doping material concentration of first doped layer 120.

In FIG. 2K, for example, first doped layer 120 may have a thickness in a range of 50 nm to 100 nm, or approximately 75 nm), and may have a doping material concentration in a range of 7×10¹⁶ atoms/cm³ to 2×10¹⁷ atoms/cm³ (e.g., approximately 1×10¹⁷ atoms/cm 3 ). In FIG. 2L, second doped layer 122 may have a thickness in a range of 50 nm to 500 nm, or approximately 300 nm), and may have a doping material concentration in a range of 3×10¹⁷ atoms/cm³ to 7×10¹⁷ atoms/cm³ (e.g., approximately 5×10¹⁷ atoms/cm³ ). In FIG. 2M, third doped layer 124 may have a thickness sufficient to fill the remainder of cavity 208, and may have a doping material concentration in a range of 8×10¹⁷ atoms/cm³ to 5×10¹⁸ atoms/cm³ (e.g., approximately 1×10¹⁸ atoms/cm³).

As described above in connection with FIG. 1E, in lieu of the deposition of individual doped layers 120, 122, and 124, doped semiconductor structure 125 may be formed (e.g., by way of conformal deposition) as a single doped region having a continuous doping material concentration gradient. Moreover, in some embodiments, the doping material concentration may generally increase from the first side of doped semiconductor structure 125 (e.g., at or near doped channel structure 114) to the second (e.g., upper) side of doped semiconductor structure 125. Further, in some embodiments, the doping concentration of doped semiconductor structure 125 at the first side may range from 7×10¹⁶ atoms/cm³ to 2×10¹⁷ atoms/cm³ (e.g., approximately 1×10¹⁷ atoms/cm³ ), and the doping concentration at the second side, or at a central region 117 of doped semiconductor structure 125, may range from 8×10¹⁷ atoms/cm³ to 5×10¹⁸ atoms/cm³ (e.g., approximately 1×10¹⁸ atoms/cm3). Further, in some embodiments, the majority of the increase in doping concentration may occur within 100 nm to 600 nm (e.g., approximately 300 nm) of the first side of doped semiconductor structure 125.

FIG. 2N illustrates the removal (e.g., by way of chemical-mechanical planarization (CMP) of a portion of doped semiconductor structure 125 (e.g., doped layers 120, 122, and 124). In some embodiments the resulting upper side of doped semiconductor structure 125 may lie below an upper side of semiconductor layer 106 (e.g., below upper doped region 112). In some embodiments, dielectric layer 130 is substantially resistant to the removal operation.

FIG. 20 illustrates the forming (e.g., by way of deposition) of upper semiconductor layer 128 on doped semiconductor structure 125. In some embodiments, upper semiconductor structure may include silicon (Si) or another semiconductor material. Also, in some embodiments, an upper side of upper semiconductor layer 128 may be planarized (e.g., using CMP) (e.g., such that the upper side of upper semiconductor layer 128 is approximately at a same height as semiconductor layer 106.

FIG. 2P illustrates the forming (e.g., by way of implantation or doping) of upper doped region 126 (e.g., an upper p-doped region, or a cell p-doped region) in upper semiconductor layer 128, and possibly extending into doped semiconductor structure 125, by way of photoresist layer 202. In some embodiments, upper doped region 126 may be approximately as wide as lower doped region 108. Also, in some embodiments, the implantation may be performed using a gas source 210 (e.g., boron (B)).

FIGS. 2Q, 2R, and 2S illustrate the forming (e.g., by way of deposition) of one or more dielectric layers 130, which may include one or more insulating barrier layers 132. In some embodiments, dielectric layers 130 may include silicon oxide (e.g., SiOₓ, such as silicon dioxide (SiO₂)), another oxide, or another dielectric material, and insulating barrier layers 132 may include, for example, silicon nitride (Si₃N₄) or another dielectric material.

FIG. 2T illustrates the forming (e.g., by way of photolithograpy and etching) of openings 212 through dielectric layers 130 and insulating barrier layers 132 to upper doped regions 112 and 126. FIG. 2U illustrates the forming (e.g., by way of deposition) of a conductive contact 136, possibly preceded by the forming of a conductive barrier layer 134, in each opening 212 and atop a dielectric layer 130. In some embodiments, the forming of conductive barrier layers 134 may be conformal, possibly unlike conductive contacts 136. In some embodiments, conductive contacts 136 may include copper (Cu), tungsten (W), aluminum (Al), or another conductive material. Further, in some embodiments, conductive barrier layer 134 may include tantalum nitride (TaN), titanium nitride (TiN), or another conductive material. Additionally, in some embodiments, the forming of conductive barrier layers 134 and conductive contacts 136 may be followed by a planarization process, such as CMP, as depicted in FIG. 2U.

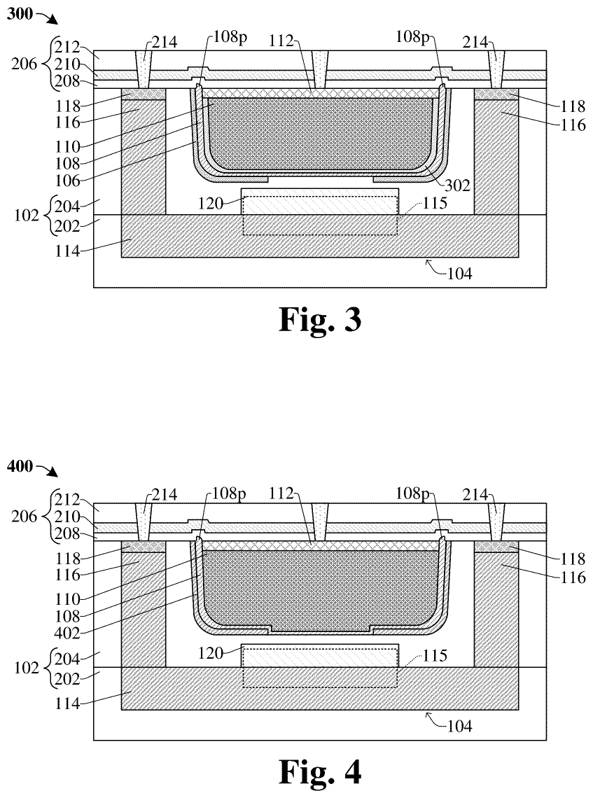

FIG. 3 illustrates a cross-sectional view of some embodiments of another IC device 300 employing a SPAD 101 with a graded doping structure, according to the present disclosure. In some embodiments, SPAD 101, as described above, is disposed in semiconductor substrate 102 and appears inverted relative to the depiction of FIG. 1A. Positioned below SPAD 101 and coupled thereto are a number of conductive layers 306 and intervening conductive vias 308 coupled to conductive contacts 136 that are, in turn, coupled to SPAD 101. Further, in some embodiments, conductive layers 306 and conductive vias 308 are disposed within a plurality of dielectric layers, including, but not limited to, dielectric layers 314, 316, 318, 320, 322, and 324, some of which may include etch stop layers, dielectric barrier layers, and so on, and may include materials such as silicon oxide (e.g., SiOₓ, such as silicon dioxide (SiO₂)), silicon nitride (Si₃N₄), another oxide, or another dielectric material. Further, an oxide bond region 304 may couple a lower side of a dielectric layer (e.g., dielectric layer 314) to a carrier wafer 302 that may include electronic components for operating SPAD 101 and/or for performing other functions.

Disposed over semiconductor substrate 102 that includes SPAD 101, in some embodiments, may be an oxide layer 326 (e.g., silicon oxycarbide (SiOC), possibly used as an optical coating), two high-kappa (κ) dielectric layers 328 and 330, another oxide layer 332, and a semiconductor (e.g., silicon (Si)) layer 334. Further, in some embodiments, a conductive layer 336 (e.g., tungsten (W)) may be disposed on semiconductor layer 334 and may extend through an opening 340 of semiconductor layer 334 positioned over SPAD 101 to facilitate reception of photons therethrough.

In addition, in some embodiments, a through-substrate via (TSV) 312 may be coupled to an outer layer 338 (e.g., where TSV 312 and outer layer 338 may include the same conductive material, such as silicon carbide (SiC)). Also, a conductive pad 310 (e.g., an aluminum (Al) pad) may be electrically coupled to TSV 312 and extend therethrough to contact a conductive layer 306, thus potentially coupling together components on alternate sides of semiconductor substrate 102.

While a single SPAD 101 is shown in IC device 300, a plurality of SPADs 101 arranged as a two-dimensional array in a plan view of IC device 300 (e.g., to create a two-dimensional IR image) may be included in IC device 300 in some embodiments.

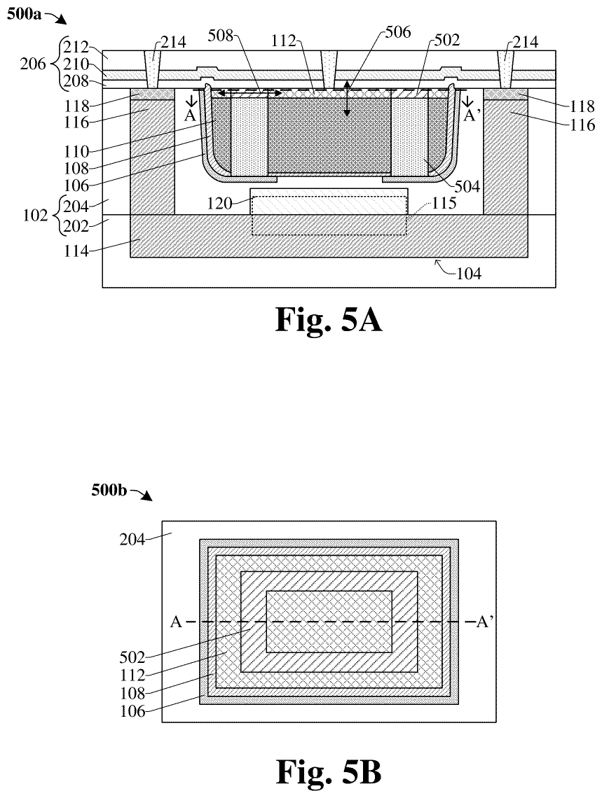

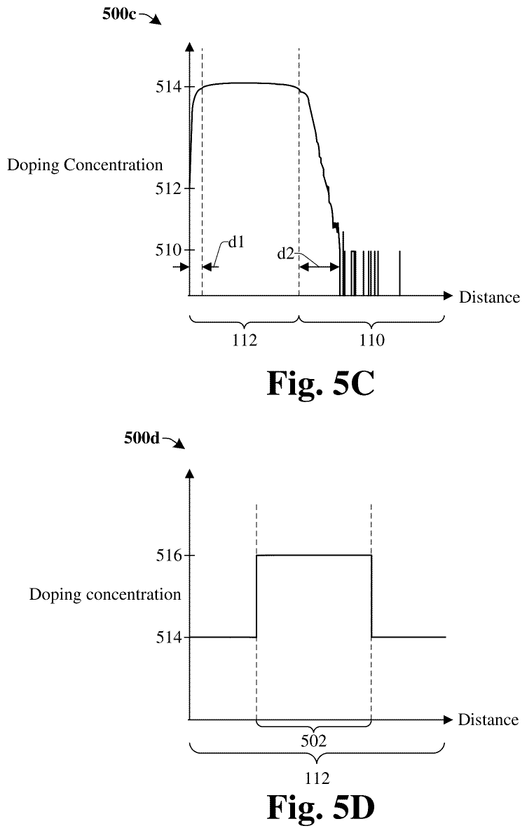

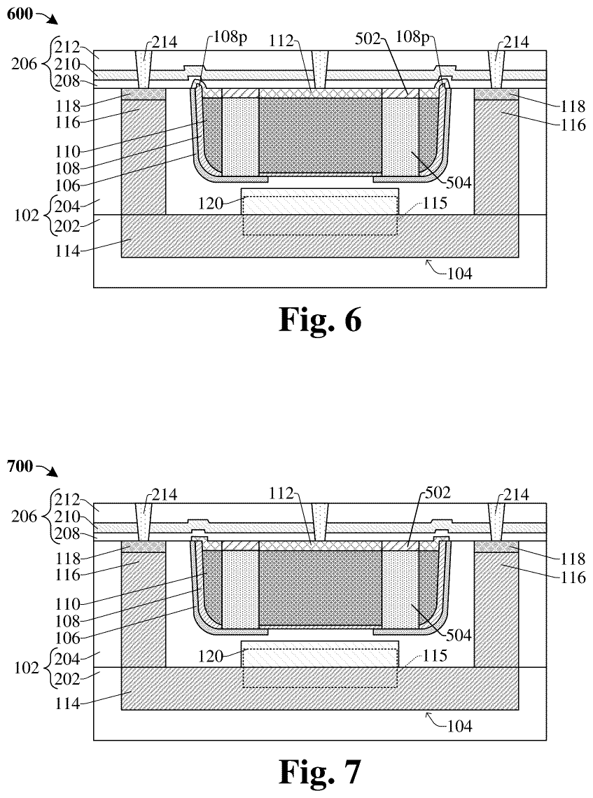

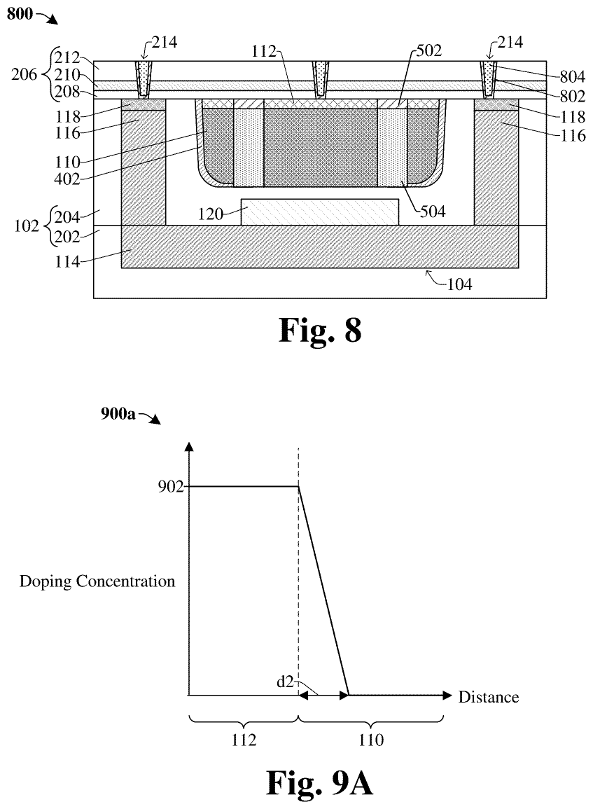

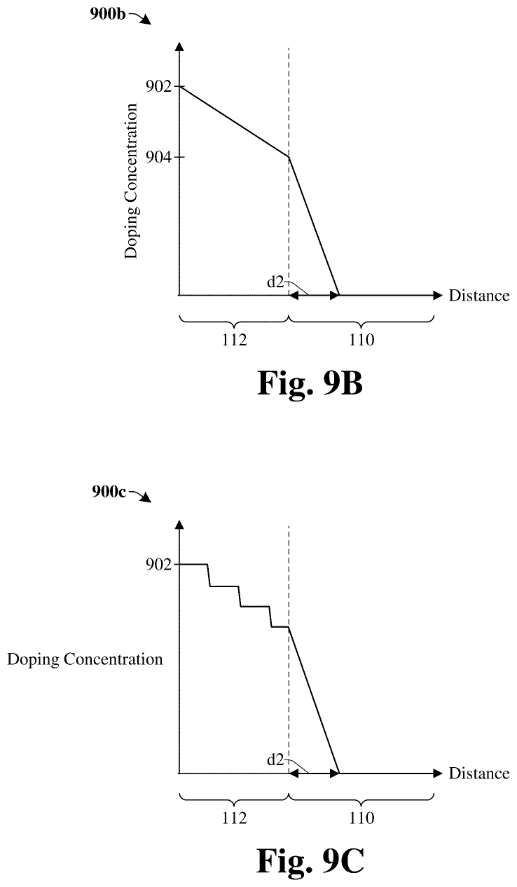

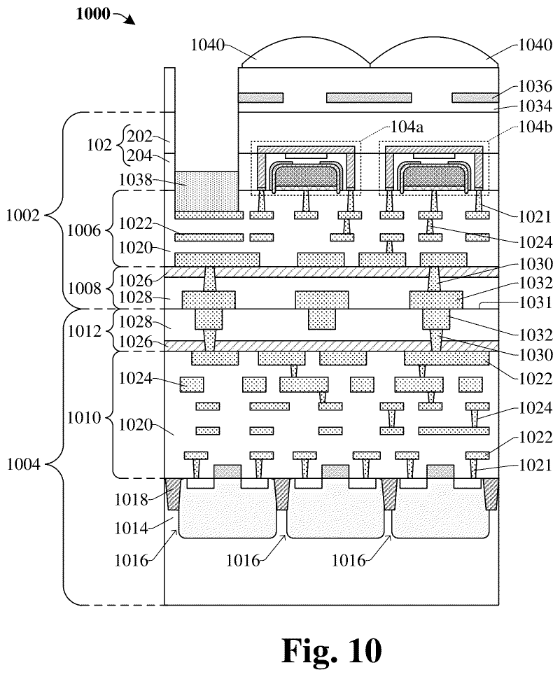

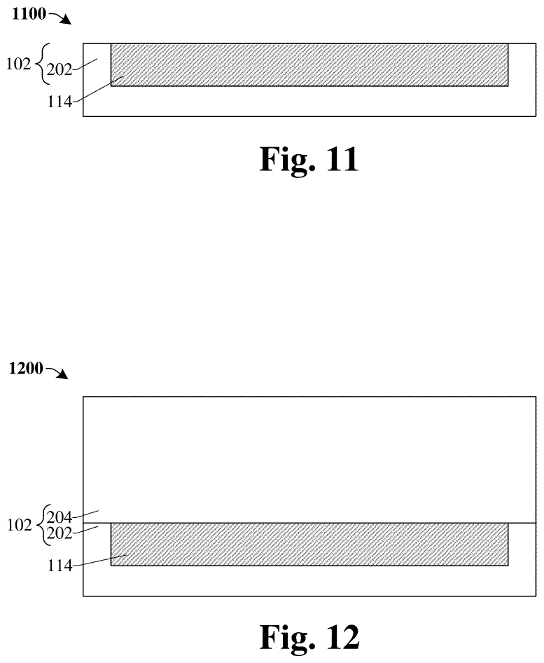

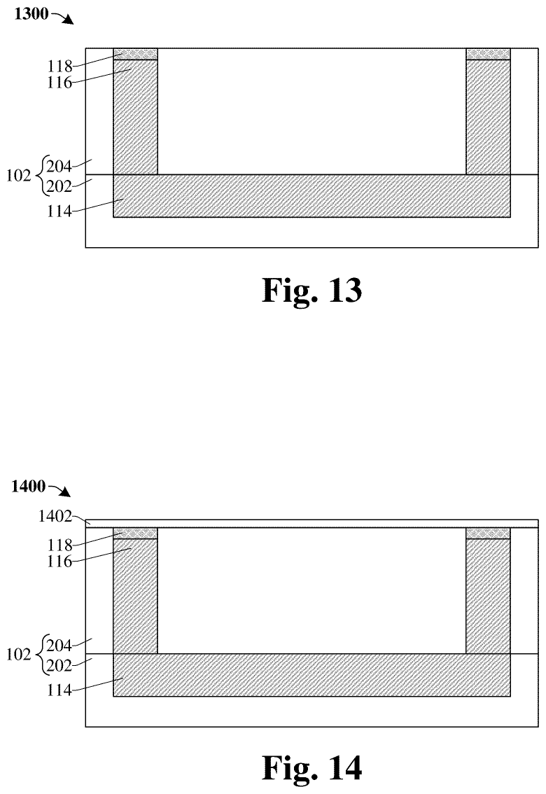

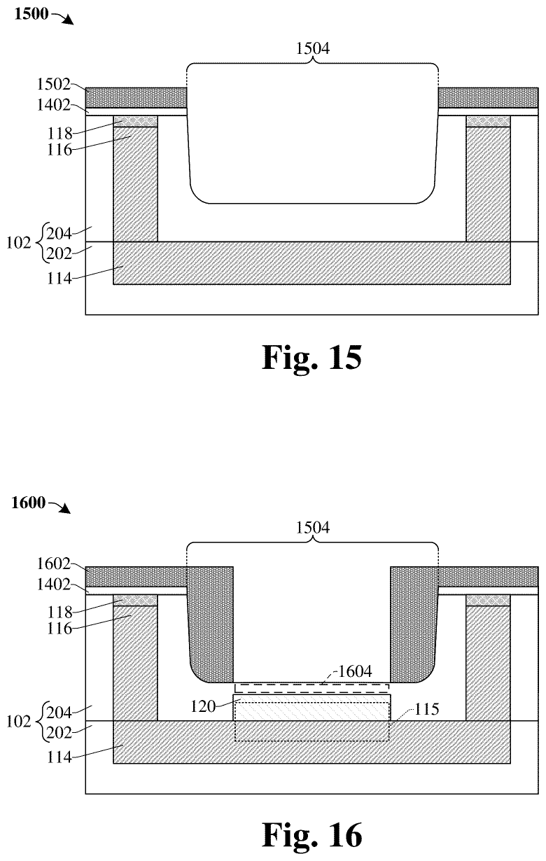

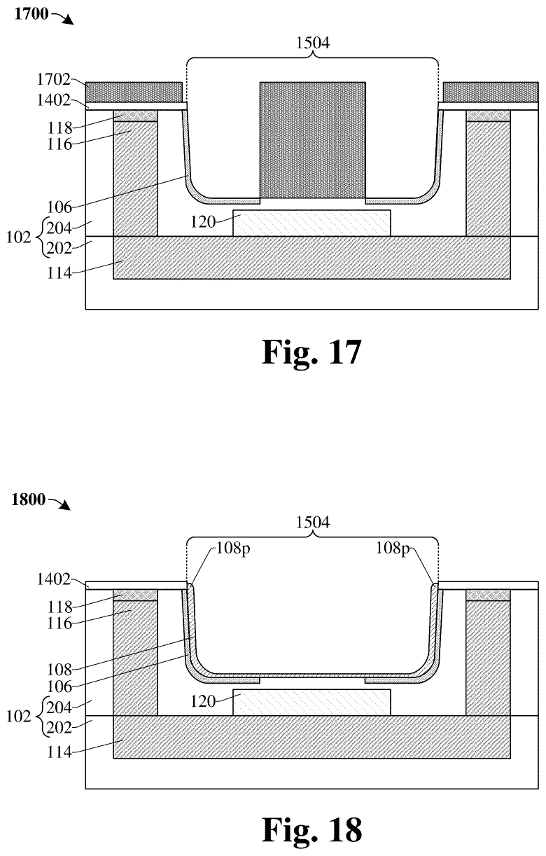

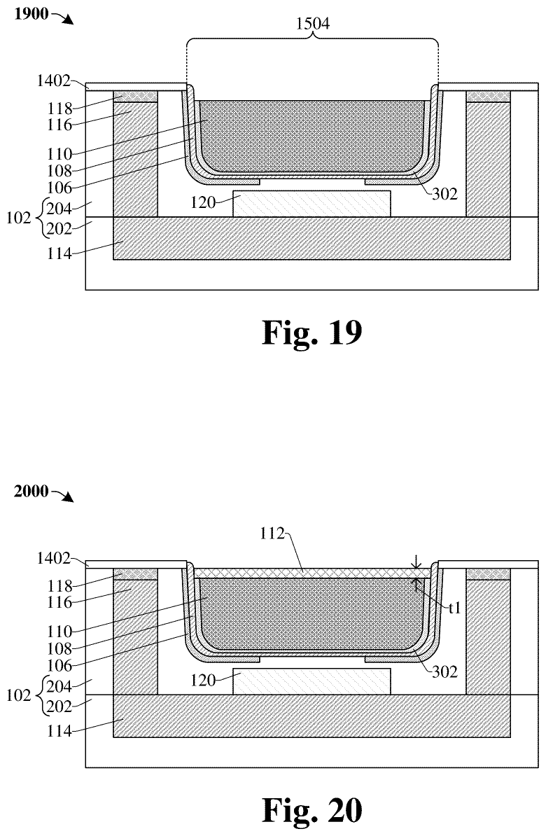

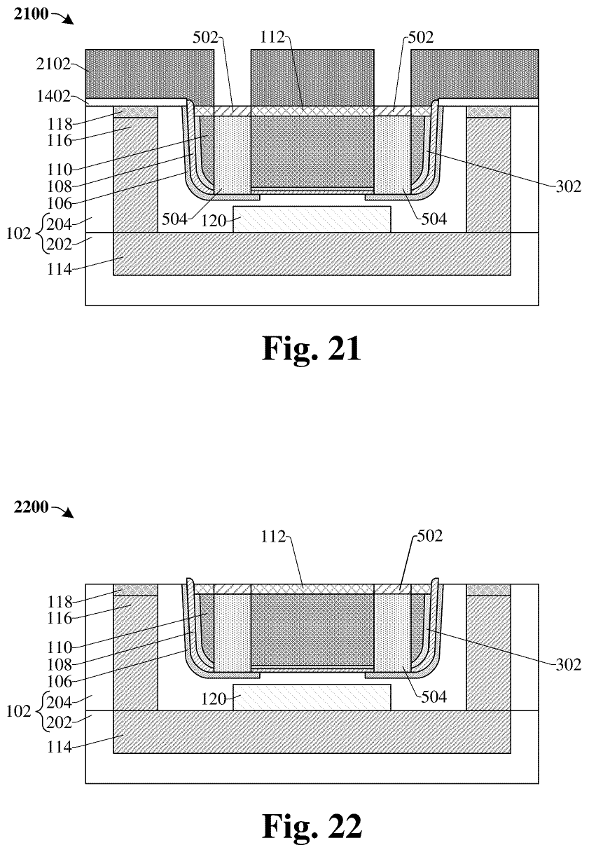

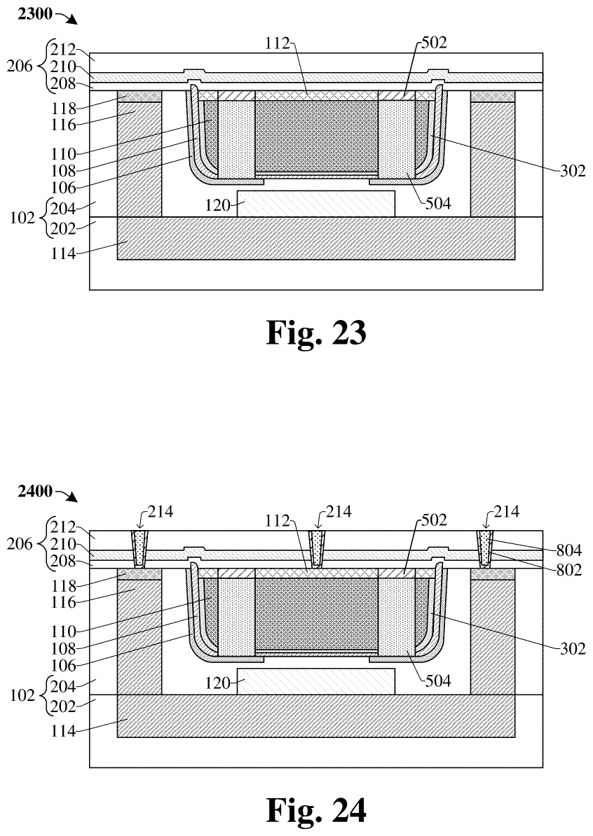

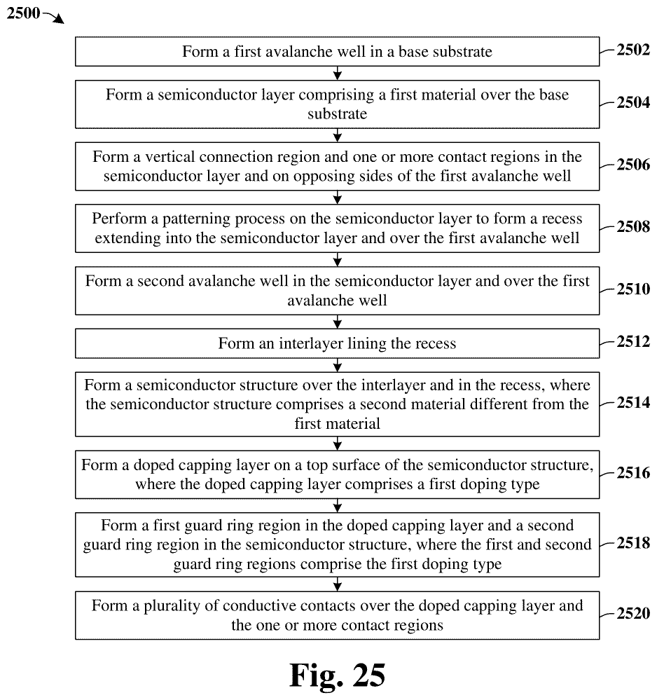

FIGS. 4 and 5 illustrate block diagrams of some embodiments of methodologies 400 and 500, respectively, of forming an IC device (e.g., IC device 100 and/or 100A of FIGS. 1A through 1E) including a SPAD (e.g., SPAD 101 and/or 101A of FIGS. 1A through 1E) having a graded doping structure, according to the present disclosure. Although these methods and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

For example, in methodology 400 of FIG. 4, at Act 402, a doped floor region (e.g., doped floor region 104 of FIG. 1A) is formed (e.g., by a first implantation process) in a semiconductor substrate (e.g., semiconductor substrate 102 of FIG. 1A). FIG. 2B illustrates a cross-sectional view of some embodiments corresponding to Act 402.

At Act 404, a semiconductor layer (e.g., semiconductor layer 106 of FIG. 1A) is formed on the semiconductor substrate. FIG. 2C illustrates a cross-sectional view of some embodiments corresponding to Act 404.

At Act 406, a doped wall region (e.g., doped wall region 110 of FIG. 1A) is formed (e.g., by a second implantation process) in the semiconductor layer. In some embodiments, the doped wall region extends upward from the doped floor region and at least partially surrounds a central region of the semiconductor layer over the doped floor region. FIG. 2D illustrates a cross-sectional view of some embodiments corresponding to Act 406.

At Act 408, a doped semiconductor structure (e.g., doped semiconductor structure 125 of FIG. 1A) is formed in the central region of the semiconductor layer. In some embodiments, the doped semiconductor structure includes a first side that faces toward the doped floor region and the doped wall region, and further includes a second side facing upward. In some embodiments, the doped semiconductor structure has a concentration of a doping material that varies from the first side to a central area of the second side. FIGS. 2K through 2N illustrate cross-sectional views of some embodiments corresponding to Act 408.

At Act 410, a dielectric structure (e.g., dielectric layers 130 and insulating barrier layer 132 of FIG. 1A) is formed over the semiconductor layer. FIGS. 2Q through 2S illustrate cross-sectional views of some embodiments corresponding to Act 410.

At Act 412, a first conductive contact (e.g., conductive contact 136 of FIG. 1A) and a second conductive contact (e.g., conductive contact 136 of FIG. 1A) are formed in the dielectric structure. In some embodiments, the first conductive contact is electrically coupled with the second side of the doped semiconductor structure and the second conductive contact is electrically coupled with an upper side of the doped wall region. FIGS. 2T and 2U illustrate cross-sectional views of some embodiments corresponding to Act 412.

In methodology 500, at Act 502, a doped floor region (e.g., doped floor region 104 of FIG. 1A) is formed in a semiconductor substrate (e.g., semiconductor substrate 102 of FIG. 1A). FIG. 2B illustrates a cross-sectional view of some embodiments corresponding to Act 502.

At Act 504, a semiconductor layer (e.g., semiconductor layer 106 of FIG. 1A) is formed on the semiconductor substrate. FIG. 2C illustrates a cross-sectional view of some embodiments corresponding to Act 504.

At Act 506, a doped wall region (e.g., doped wall region 110 of FIG. 1A) is formed in the semiconductor layer on a lateral peripheral area of the doped floor region in the semiconductor layer to surround a central region of the semiconductor layer over the doped floor region in a plan view of the semiconductor substrate. FIG. 2D illustrates a cross-sectional view of some embodiments corresponding to Act 506.

At Act 508, a cavity (e.g., cavity 208 of FIG. 2G) is formed (e.g., by way of etching) via an upper side of the semiconductor layer in the central region of the semiconductor layer. In some embodiments, the cavity includes a floor and a wall surrounding the floor in the plan view of the semiconductor substrate. FIG. 2G illustrates a cross-sectional view of some embodiments corresponding to Act 508.

At Act 510, a doped semiconductor structure (e.g., doped semiconductor structure 125 of FIG. 1A) is formed in the cavity of the semiconductor layer. In some embodiments, the doped semiconductor structure has a concentration of a doping material that increases from the floor and the wall of the cavity to a central region (e.g., central region 117 of FIG. 1A) of the doped semiconductor structure. In some embodiments, the doped semiconductor structure may include one of (1) a plurality of doped layers (e.g., doped layers 120, 122, and 124 of FIG. 1A), where each of the doped layers has a corresponding concentration of the doping material, or (2) a single doped region (e.g., doped semiconductor structure 125 of FIG. 1E) having a continuous gradient profile for the concentration of the doping material. FIGS. 2K through 2N illustrate cross-sectional views of some embodiments corresponding to Act 510.

At Act 512, a dielectric structure (e.g., dielectric layers 130 and insulating barrier layer 132 of FIG. 1A) is formed over the semiconductor layer. FIGS. 2Q through 2S illustrate cross-sectional views of some embodiments corresponding to Act 512.

At Act 514, a first conductive contact (e.g., conductive contact 136 of FIG. 1A) and a second conductive contact (e.g., conductive contact 136 of FIG. 1A) are formed in the dielectric structure. In some embodiments, the first conductive contact is electrically coupled with an upper side of the doped semiconductor structure and the second conductive contact is electrically coupled with an upper side of the doped wall region. FIGS. 2T and 2U illustrate cross-sectional views of some embodiments corresponding to Act 514.

In some embodiments, the present disclosure provides an IC device, including: a semiconductor substrate including a doped floor region; a semiconductor layer on the semiconductor substrate, the semiconductor layer including a doped wall region extending upward from the doped floor region and at least partially surrounding a central region of the semiconductor layer over the doped floor region; a doped semiconductor structure in the central region of the semiconductor layer, the doped semiconductor structure including a first side that faces toward the doped floor region and the doped wall region, the doped semiconductor structure further including a second side facing upward, the doped semiconductor structure having a concentration of a doping material that increases from the first side to a central area of the second side; and a first conductive contact and a second conductive contact in a dielectric structure over the semiconductor layer, where the first conductive contact is electrically coupled with the second side of the doped semiconductor structure and the second conductive contact is electrically coupled with an upper side of the doped wall region.

In some embodiments, the present disclosure provides a method of fabricating an IC device. The method includes: performing a first implantation process to form a doped floor region in a semiconductor substrate; forming a semiconductor layer on the semiconductor substrate; performing a second implantation process to form a doped wall region in the semiconductor layer, the doped wall region extending upward from the doped floor region and at least partially surrounding a central region of the semiconductor layer over the doped floor region; forming a doped semiconductor structure in the central region of the semiconductor layer, the doped semiconductor structure including a first side that faces toward the doped floor region and the doped wall region, the doped semiconductor structure further including a second side facing upward, the doped semiconductor structure having a concentration of a doping material that varies from the first side to a central area of the second side; forming a dielectric structure over the semiconductor layer; and forming a first conductive contact and a second conductive contact in the dielectric structure, where the first conductive contact is electrically coupled with the second side of the doped semiconductor structure and the second conductive contact is electrically coupled with an upper side of the doped wall region.

In some embodiments, the present disclosure provides another method of fabricating an IC device. The method includes: forming a doped floor region in a semiconductor substrate; forming a semiconductor layer on the semiconductor substrate; forming a doped wall region in the semiconductor layer on a lateral peripheral area of the doped floor region in the semiconductor layer to surround a central region of the semiconductor layer over the doped floor region in a plan view of the semiconductor substrate; forming a cavity via an upper side of the semiconductor layer in the central region of the semiconductor layer, the cavity including a floor and a wall surrounding the floor in the plan view of the semiconductor substrate; forming a doped semiconductor structure in the cavity of the semiconductor layer, the doped semiconductor structure having a concentration of a doping material that increases from the floor and the wall of the cavity to a central region of the doped semiconductor structure, where the doped semiconductor structure includes one of a plurality of doped layers, wherein each of the plurality of doped layers includes a corresponding concentration of the doping material, or a single doped region including a continuous gradient profile for the concentration of the doping material; forming a dielectric structure over the semiconductor layer; and forming a first conductive contact and a second conductive contact in the dielectric structure, where the first conductive contact is electrically coupled with an upper side of the doped semiconductor structure and the second conductive contact is electrically coupled with an upper side of the doped wall region.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising a first material and opposing sidewalls defining a recess;
a semiconductor structure in the recess and comprising a second material different from the first material; and
a doped capping layer over the semiconductor structure, wherein the doped capping layer comprises a first doping type, wherein the doped capping layer covers a top surface of the semiconductor structure and extends laterally between opposing sidewalls of the semiconductor structure.

2. The semiconductor device of claim 1, further comprising:
a first guard ring region in the doped capping layer and having the first doping type, wherein a doping concentration of the first guard ring region is greater than a doping concentration of regions of the doped capping layer laterally offset from the first guard ring region; and
a second guard ring region in the semiconductor structure and under the first guard ring region, wherein the second guard ring region has the first doping type.

3. The semiconductor device of claim 2, wherein the doping concentration of the regions of the doped capping layer laterally offset from the first guard ring region is greater than a doping concentration of the second guard ring region.

4. The semiconductor device of claim 2, wherein in cross-sectional view the first guard ring region and the second guard ring region are arranged on opposing sides of a middle region of the semiconductor structure, and wherein in top view the first guard ring region and the second guard ring region are closed loop.

5. The semiconductor device of claim 1, further comprising:
an interlayer arranged between the semiconductor structure and the substrate, wherein the interlayer extends along the opposing sidewalls of the semiconductor structure and a lower surface of the semiconductor structure, wherein the interlayer comprises the first material, and wherein a thickness of the interlayer is less than a thickness of the doped capping layer.

6. The semiconductor device of claim 5, wherein the interlayer comprises a protrusion that extends above a top surface of the substrate, wherein a height of the protrusion is less than the thickness of the doped capping layer.

7. The semiconductor device of claim 6, wherein in cross-sectional view the protrusion comprises a pair of segments on opposing sides of the semiconductor structure, and wherein in top view the protrusion is ring-shaped and continuously extends around a perimeter of the semiconductor structure.

8. The semiconductor device of claim 1, wherein a doping concentration of at least a middle region of the doped capping layer is substantially constant at a first value across a thickness of the doped capping layer, wherein an upper region of the semiconductor structure comprises the first doping type, wherein a doping concentration of the upper region continuously decreases from the first value to a second value, wherein the semiconductor structure comprises a lower region under the upper region that is undoped or comprises the first doping type having a doping concentration equal to or less than the second value, wherein a thickness of the upper region of the semiconductor structure is about 5% or less of a thickness of the semiconductor structure.

9. The semiconductor device of claim 1, wherein a doping concentration of at least a middle region of the doped capping layer discretely decreases at least three times from a top surface of the doped capping layer in a direction towards the semiconductor structure, wherein a doping concentration of the first doping type in the semiconductor structure is less than a minimum doping concentration of the doped capping layer.

10. The semiconductor device of claim 1, further comprising:
a first avalanche well in the substrate and under the semiconductor structure;
a vertical connection region in the substrate and on opposing sides of the semiconductor structure, where the vertical connection region overlies the first avalanche well;
a first contact region in the substrate and over the vertical connection region, wherein the first avalanche well, the vertical connection region, and the first contact region comprise a second doping type opposite the first doping type; and
a second avalanche well in the substrate and between the first avalanche well and the semiconductor structure, wherein the second avalanche well comprises the first doping type, wherein a doping concentration of the doped capping layer is greater than doping concentrations of the first and second avalanche wells.

11. A method for forming a semiconductor device, comprising:
forming a first semiconductor well in a substrate, wherein the substrate comprises a first material;
patterning the substrate to form a recess in the substrate over the first semiconductor well;
forming a second semiconductor well in the substrate and over the first semiconductor well, wherein a semiconductor region is defined by a PN junction between the first semiconductor well and the second semiconductor well;
forming a semiconductor structure in the recess and over the second semiconductor well, wherein the semiconductor structure comprises a second material having a bandgap different than the first material; and
forming a doped capping layer along a top surface of the semiconductor structure, wherein forming the doped capping layer comprises in-situ doping the doped capping layer with one or more dopants having a first doping type.

12. The method of claim 11, wherein the first and second semiconductor wells are avalanche wells, wherein the first semiconductor well has a second doping type opposite the first doping type, wherein the second semiconductor well has the first doping type, and wherein a doping concentration of the doped capping layer is greater than doping concentrations of the first and second semiconductor wells.

13. The method of claim 11, further comprising:
forming a seed layer lining the recess and between the semiconductor structure and the substrate, wherein the seed layer extends along opposing sidewalls and a bottom surface of the semiconductor structure, wherein the seed layer comprises the second material, and wherein the doped capping layer contacts a top surface of the seed layer.

14. The method of claim 13, wherein the semiconductor structure and the seed layer have the first doping type, wherein a doping concentration of the seed layer is less than a doping concentration of the semiconductor structure, and wherein the doping concentration of the semiconductor structure is less than a doping concentration of the doped capping layer.

15. The method of claim 11, further comprising:
performing an implantation process on the doped capping layer and the semiconductor structure to form a first guard ring region in the doped capping layer and a second guard ring region in the semiconductor structure, wherein the first guard ring region and the second guard ring region have the first doping type, and wherein a doping concentration of the first guard ring region is greater than a doping concentration of adjacent regions of the doped capping layer and a doping concentration of the second guard ring region.

16. The method of claim 11, wherein a doping concentration of the doped capping layer decreases from a top surface of the doping capping layer in a direction towards the semiconductor structure.

17. A method for forming a semiconductor device, comprising:
performing a first implantation process to form a first semiconductor well in a substrate, wherein the substrate comprises a first material;
performing a second implantation process to form a vertical connection region and a first contact region in the substrate and over outer regions of the first semiconductor well, wherein the first contact region overlies the vertical connection region;
patterning the substrate to form a recess extending into the substrate and over the first semiconductor well;
performing a third implantation process to form a second semiconductor well in the substrate and over the first semiconductor well, wherein the second semiconductor well comprises a first doping type and the first semiconductor well, the vertical connection region, and the first contact region comprise a second doping type opposite the first doping type;
forming an interlayer lining the recess, wherein the interlayer comprises the first material;
forming a semiconductor structure over the interlayer and in the recess, wherein the semiconductor structure comprises a second material different from the first material; and
selectively forming a doped capping layer along a top surface of the semiconductor structure, wherein the doped capping layer continuously laterally extends between inner sidewalls of the interlayer, and wherein selectively forming the doped capping layer includes flowing a dopant gas while growing or depositing the doped capping layer over the semiconductor structure, such that the doped capping layer comprises the first doping type.

18. The method of claim 17, wherein a flow rate of the dopant gas is varied while depositing or growing the doped capping layer, such that the doped capping layer has a gradient doping profile or a graded doping profile.

19. The method of claim 17, wherein the doped capping layer extends over and contacts a top surface of the interlayer, and wherein outer regions of the doped capping layer directly contact a top surface of the substrate.

20. The method of claim 17, wherein the interlayer is undoped and has a thickness less than a thickness of the doped capping layer.
